(19) United States
(12) Patent Application Publication
(10) Pub. No.: US 2011/0300354 A1
(43) Pub. Date: Dec. 8, 2011

(54) COMBINED SUBSTRATE AND METHOD FOR MANUFACTURING SAME

(75) Inventor: Taro NISHIGUCHI, Itami-shi (JP)

(73) Assignee: SUMITOMO ELECTRIC INDUSTRIES, LTD., Osaka-shi (JP)

(21) Appl. No.: 13/117,474

(22) Filed: May 27, 2011

(30) Foreign Application Priority Data
Jun. 4, 2010 (JP) 2010-129099

(51) Int. Cl. C30B 23/02; B32B 3/10; B32B 9/04

(52) U.S. Cl. 428/210; 117/106; 428/448

(57) ABSTRACT

A base portion is prepared which has a supporting layer made of a material different from silicon carbide, and a silicon carbide layer formed on the supporting layer. Each of first and second silicon carbide single-crystals is connected onto the silicon carbide layer of the base portion. In this way, a combined substrate having such a plurality of silicon carbide single-crystals can be provided at low cost.

### BACKGROUND OF THE INVENTION

1. Field of the Invention

The present invention relates to a combined substrate and a method for manufacturing the combined substrate, in particular, a combined substrate having a plurality of silicon carbide single-crystals and a method for manufacturing such a combined substrate.

2. Description of the Background Art

In recent years, silicon carbide substrates have been adopted as semiconductor substrates for use in manufacturing semiconductor devices. Silicon carbide has a band gap larger than that of silicon, which has been used more commonly. Hence, a semiconductor device employing a silicon carbide substrate advantageously has a large reverse breakdown voltage, low on-resistance, and properties less likely to decrease in a high temperature environment, advantageously.

In order to efficiently manufacture such semiconductor devices, the substrates need to be large in size to some extent. According to U.S. Pat. No. 7,314,520, a silicon carbide substrate of 76 mm (3 inches) or greater can be manufactured. Industrially, the size of a silicon carbide substrate is, however, still limited to approximately 100 mm (4 inches). In particular, in the case where the substrate has a plane orientation other than the (0001) plane in the hexagonal system, it is more difficult to secure a size required therefor. This is because an ingot of silicon carbide is usually formed by growth in the (0001) plane in order to restrain occurrence of stacking fault.

In view of this, as a substitute for one large silicon carbide single-crystal, US Patent Publication No. 2004/0187766 proposes a combined substrate having a supporting portion and a plurality of silicon carbide single-crystals connected onto the supporting base. This structure is obtained by adhering the silicon carbide single-crystals onto the supporting portion, which is made of graphite for example, by means of a graphite adhesive agent.

The connection achieved between each of the silicon carbide single-crystals and the graphite substrate as described above is adhesion between the members made of different types of materials. If silicon carbide is also employed for the material of the supporting portion, the connection therebetween is adhesion between members made of the same type of material. However, it takes a long time to form such a supporting portion. This is due to the following reason. That is, the supporting portion needs to have a certain thickness to secure rigidity required for handling, whereas silicon carbide is normally grown by means of vapor phase epitaxy, by which growth rate is slow. Due to the reason, cost is high in manufacturing the combined substrate using the conventional method, disadvantageously.

### SUMMARY OF THE INVENTION

The present invention is made in view of the foregoing problem, and its object is to provide a combined substrate having a plurality of silicon carbide single-crystals at low cost.

A method for manufacturing a combined substrate in the present invention includes the following steps. There is prepared a base portion having a supporting layer made of a material different from silicon carbide, and a silicon carbide layer formed on the supporting layer. Each of first and second silicon carbide single-crystals is connected onto the silicon carbide layer of the base portion.

According to the present manufacturing method, the connection between each silicon carbide single-crystal and the base portion supporting the silicon carbide single-crystal can be a connection between the members made of the same type of material. Further, the base portion supporting the silicon carbide single-crystals has the supporting layer in addition to the silicon carbide layer. This secures rigidity required for handling of the combined substrate while the silicon carbide layer made of silicon carbide whose growth rate is slow can be thin in the base portion. In this way, the base portion can be formed for a short time, thereby manufacturing the combined substrate at low cost.

Preferably, the step of connecting includes the following steps. Each of the first and second silicon carbide single-crystals is arranged to face the silicon carbide layer. The silicon carbide layer is connected to each of the first and second silicon carbide single-crystals by sublimating and recrystallizing, onto the first and second silicon carbide single-crystals, the silicon carbide layer's portions respectively facing the first and second silicon carbide single-crystals. In this way, the connection can be firm.

More preferably, the step of arranging is performed by stacking a single-crystal group and the base portion on each other, the single-crystal group having the first and second silicon carbide single-crystals disposed at different locations when viewed in a planar view. In this way, the step of arranging can be performed readily.

The supporting layer may include a layer made of graphite. Further, the supporting layer may include a layer made of a metal having a melting point higher than a temperature at which silicon carbide is able to sublime. This achieves improved stability of the supporting layer at a high temperature.

Preferably, each of the silicon carbide layer, the first silicon carbide single-crystal, and the second silicon carbide single-crystal has a crystal structure of the same polytype. This can prevent warpage or crack of the combined substrate.

A combined substrate of the present invention includes a base portion and first and second silicon carbide single-crystals. The base portion has a supporting layer and a silicon carbide layer. The supporting layer is made of a material different from silicon carbide. The silicon carbide layer is formed on the supporting layer. Each of the first and second silicon carbide single-crystals is connected onto the silicon carbide layer. The silicon carbide layer has a first region facing the supporting layer, and a second region buried in the first region and epitaxially grown on each of the first and second silicon carbide single-crystals.

According to the present combined substrate, an interface between the first silicon carbide single-crystal and the second region epitaxially grown thereon corresponds to an interface between the first silicon carbide single-crystal and the base portion. This allows for firm connection between the first silicon carbide single-crystal and the base portion. For the same reason, the connection between the second silicon carbide single-crystal and the base portion also becomes firm.

Preferably, the silicon carbide layer has a void between the first and second regions. This relaxes stress at a boundary between the first and second regions.

In the description above, the first and second silicon carbide single-crystals are illustrated. This is not intended to exclude an embodiment having one or more additional silicon carbide single-crystals in addition to the first and second silicon carbide single-crystals.

As apparent from the above description, according to the present invention, a combined substrate having a plurality of silicon carbide single-crystals can be provided at low cost.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a configuration of a combined substrate in a first embodiment of the present invention.

FIG. 2 is a schematic cross sectional view taken along a line II-II in FIG. 1.

FIG. 3 is a partial enlarged view of FIG. 2.

FIGS. 4 and 5 are cross sectional views schematically showing first and second steps of a method for manufacturing the combined substrate in the first embodiment of the present invention.

FIG. 6 is a partial enlarged view of FIG. 5.

FIG. 7 is a partial cross sectional view schematically showing a third step of the method for manufacturing the combined substrate in the first embodiment of the present invention, so as to illustrate how silicon carbide is transferred.

FIG. 8 is a partial cross sectional view schematically showing the same step as that in FIG. 7, so as to illustrate how a space is transferred.

FIG. 9 is a partial cross sectional view schematically showing a fourth step of the method for manufacturing the combined substrate in the first embodiment of the present invention.

FIG. 10 is a partial cross sectional view showing a combined substrate of a comparative example.

FIG. 11 is a partial cross sectional view schematically showing a configuration of a semiconductor device in a second embodiment of the present invention.

FIG. 12 is a schematic flowchart showing a method for manufacturing the semiconductor device in the second embodiment of the present invention.

FIGS. 13-17 are partial cross sectional views schematically showing first to fifth steps of the method for manufacturing the semiconductor device in the second embodiment of the present invention.

### DESCRIPTION OF THE PREFERRED EMBODIMENTS

The following describes embodiments of the present invention with reference to figures.

### First Embodiment

First, a configuration of a combined substrate of the present embodiment will be schematically described.

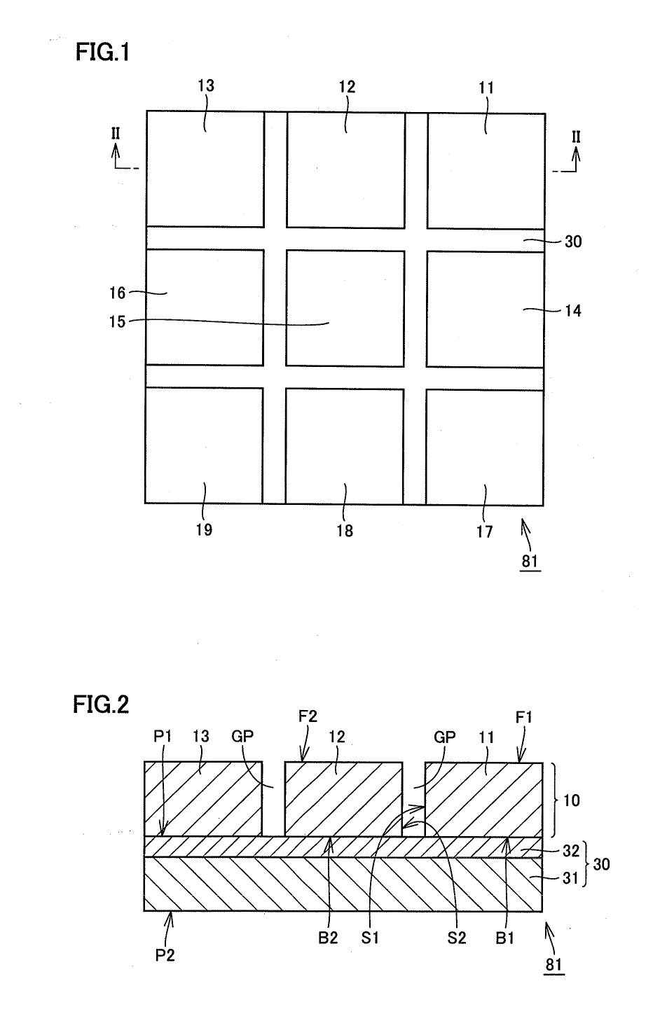

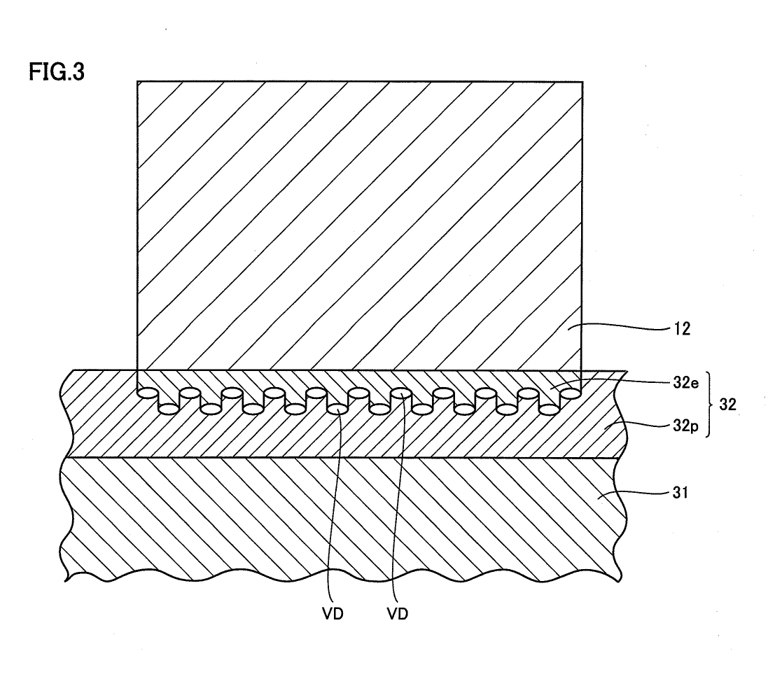

As shown in FIG. 1 and FIG. 2, combined substrate 81 of the present embodiment includes a single-crystal group 10 having single-crystal substrates 11-19 (silicon carbide single-crystals), and a base portion 30. Each of single-crystal substrates 11-19 is a plate-like silicon carbide single-crystal. Base portion 30 has a supporting layer 31 and a silicon carbide layer 32. Base portion 30 has a quadrangular shape shown in FIG. 1 or a circular shape, for example. In the case where base portion 30 has a circular shape, base portion 30 preferably has a diameter of 20 cm or greater. Preferably, in order to facilitate handling of combined substrate 81, combined substrate 81 has a thickness (dimension in the vertical direction in FIG. 2) of 300 μm or greater.

Base portion 30 is connected to each of the backside surfaces of single-crystal substrates 11-19 (surfaces opposite to the surfaces shown in FIG. 1), whereby single-crystal substrates 11-19 are fixed to one another. Single-crystal substrates 11-19 respectively have exposed front-side surfaces on the same plane. For example, single-crystal substrates 11 (first silicon carbide single-crystal) and 12 (second silicon carbide single-crystal) respectively have front-side surfaces F1 and F2 (FIG. 2). In this way, combined substrate 81 has a front-side surface larger than that of each one in single-crystal substrates 11-19. Hence, in the case of using combined substrate 81, semiconductor devices can be manufactured more effectively than in the case of using each one in single-crystal substrates 11-19 solely.

The following describes a configuration of combined substrate 81 in detail.

Base portion 30 has supporting layer 31, and silicon carbide layer 32 formed on supporting layer 31. Further, base portion 30 has a main surface P1 (first main surface) located at the silicon carbide layer 32 side, and a main surface P2 (second main surface) located at the supporting layer 31 side and opposite to main surface P1.

Supporting layer 31 is made of a material different from silicon carbide. An example of the material of supporting layer 31 is graphite or a metal having a melting point higher than a temperature at which silicon carbide can sublime. Accordingly, supporting layer 31 has a high conductivity, and a high stability at a high temperature. Examples of such a metal include tantalum, tungsten, molybdenum, titanium, zirconium, and hafnium. Supporting layer 31 may have either of a structure constituted by one layer and a structure constituted by a plurality of layers. In the case where supporting layer 31 is constituted by a plurality of layers, the plurality of layers do not need to be made of the same material. Supporting layer 31 has a thickness of, for example, approximately 300 μm.

Silicon carbide layer 32 has a thickness of, for example, approximately 20 μm. Silicon carbide layer 32 may have any crystal structure of a single-crystal structure, a polycrystal structure, and an amorphous structure. For example, silicon carbide layer 32 has a polycrystal structure of polytype 3C. Silicon carbide layer 32 preferably has a small electrical resistivity. Specifically, this electrical resistivity is preferably less than 50 mΩ·cm, more preferably, less than 10 mΩ·cm. For reduced electrical resistivity, silicon carbide layer 32 may have an impurity. For example, silicon carbide layer 32 has an n type impurity concentration of 5×10¹⁹ cm⁻³.

Each one in single-crystal group 10 is made of silicon carbide, and preferably has the same crystal structure. In addition, single-crystal group 10 preferably has a crystal structure of hexagonal system, more preferably of polytype 4H. Further, single-crystal group 10 has a defect density lower than the defect density of silicon carbide layer 32. For example, single-crystal group 10 has a micro pipe density of 0.2 cm⁻², and a stacking fault density of less than 1 cm⁻¹. Furthermore, single-crystal group 10 may has an impurity. For example, single-crystal group 10 has an n type impurity concentration of 1×10¹⁹ cm⁻³.

Each one in single-crystal group 10 has a backside surface and a front-side surface opposite to each other, and has side surfaces connecting the backside surface and the front-side surface to each other. For example, single-crystal substrate 11 (first silicon carbide single-crystal) has backside surface B1 and front-side surface F1 opposite to each other, as well as a side surface S1 connecting backside surface B1 and front-side surface F1 to each other. Single-crystal substrate 12 (second silicon carbide single-crystal) has backside surface B2 and front-side surface F2 opposite to each other, as well as a side surface S2 connecting backside surface B2 and front-side surface F2 to each other. Each one in single-crystal group 10 has a planar shape of square with 35 mm×35 mm, and has a thickness of 300 μm. The backside surface of each one in single-crystal group 10 is connected to main surface P1 of base portion 30, i.e., silicon carbide layer 32. Furthermore, gaps GP are formed between adjacent ones of single-crystal substrates 11-19. Thus, for example, side surfaces S1 and S2 face each other with gap GP interposed therebetween. It should be noted that gaps GP do not need to separate single-crystal substrates 11-19 from one another completely. For example, side surface S1 may have a portion in contact with a portion of side surface S2.

As shown in FIG. 3, silicon carbide layer 32 has a first region 32p and a second region 32e. First region 32p faces supporting layer 31. Second region 32e is buried in first region 32p, and has been epitaxially grown on each of single-crystal substrates 11-19 (only single-crystal substrate 12 is shown in FIG. 3). First region 32p may have any crystal structure of a polycrystal structure, an amorphous structure, and a single-crystal structure.

Further, silicon carbide layer 32 has voids VD between the first and second regions. Accordingly, stress can be relaxed at a boundary between first and second regions 32p, 32e.

The following describes a method for manufacturing combined substrate 81. It should be noted that for ease of description, only single-crystal substrates 11 and 12 of single-crystal substrates 11-19 may be explained, but single-crystal substrates 13-19 are handled in the same manner as single-crystal substrates 11 and 12.

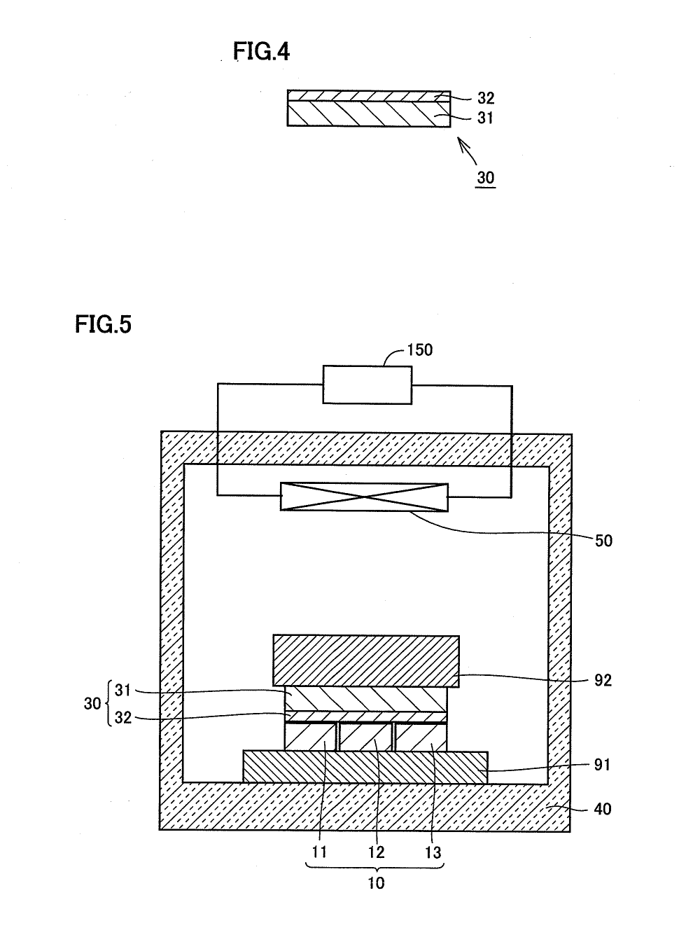

Referring to FIG. 4, supporting layer 31 is prepared. Next, silicon carbide layer 32 is formed on supporting layer 31. As a formation method, a CVD method is employed, for example. In this way, base portion 30 is prepared which has supporting layer 31 and silicon carbide layer 32 formed on supporting layer 31. In-plane variation in the thickness of base portion 30 is preferably small, for example, is less than 10 μm.

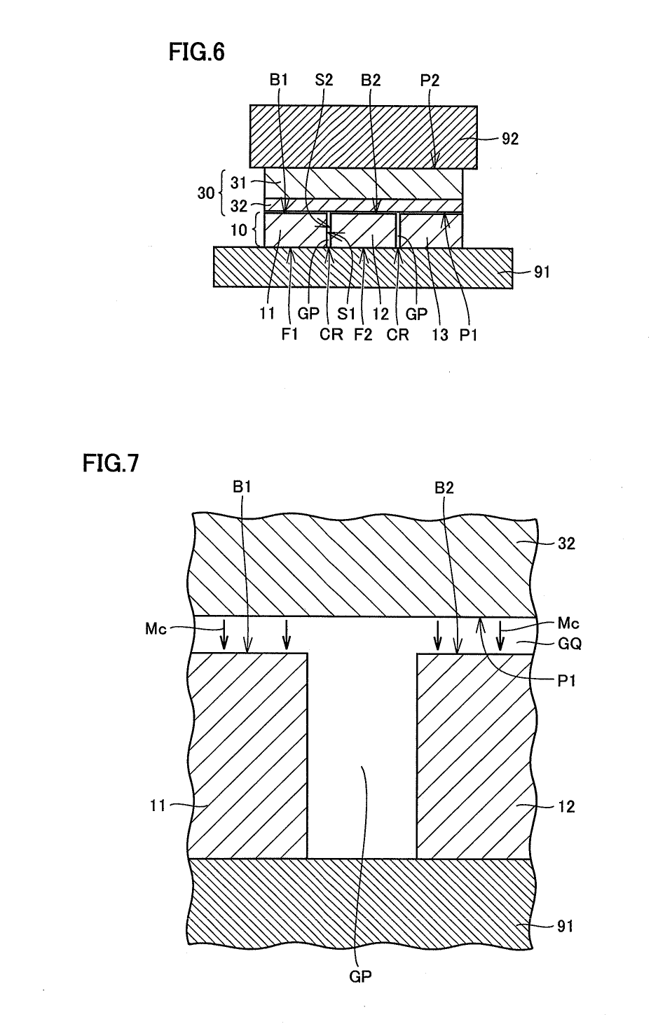

Referring to FIG. 5 and FIG. 6, base portion 30, single-crystal substrates 11-19, i.e., single-crystal group 10, and a heating device are prepared.

Specifically, for example, each one in single-crystal group 10 is prepared by cutting, along the (03-38) plane, a SiC ingot grown in the (0001) plane in the hexagonal system. In this case, preferably, the (03-38) plane side is employed for the backside surface thereof, and the (0-33-8) plane side is employed for the front-side surface thereof. In-plane variation in the thickness of each one in single-crystal group 10 is preferably small, for example, is less than 10 μm.

The heating device has first and second heating members 91, 92, a heat insulation container 40, a heater 50, and a heater power source 150. Heat insulation container 40 is formed of a highly thermally insulating material. Heater 50 is, for example, an electric resistance heater. First and second heating members 91, 92 have a function of absorbing heat emitted from heater 50 and emitting the absorbed heat so as heat base portion 30 and single-crystal group 10. Each of first and second heating members 91, 92 is formed of, for example, graphite with a small porosity.

Next, first heating member 91, single-crystal group 10, base portion 30, and second heating member 92 are arranged to be stacked on one another in this order. Specifically, first, single-crystal substrates 11-19 are arranged at different locations on first heating member 91, when viewed in a planar view. They are arranged, for example, in the form of matrix. Single-crystal substrates 11 and 12 are placed on first heating member 91 such that side surfaces S1 and S2 face each other with gap GP interposed therebetween. Then, single-crystal group 10 and base portion 30 are stacked on each other such that each one in single-crystal group 10 and silicon carbide layer 32 of base portion 30 face each other. Then, second heating member 92 is placed on base portion 30. Then, the first heating member, single-crystal group 10, base portion 30, and the second heating member thus stacked on one another are accommodated in heat insulation container 40 having heater 50 provided therein.

Next, the atmosphere in heat insulation container 40 is adapted to be an atmosphere obtained by reducing the pressure of atmospheric air, or an inert gas atmosphere. An exemplary inert gas usable is a noble gas such as He or Ar; a nitrogen gas; or a mixed gas of the noble gas and nitrogen gas. For example, the atmosphere is nitrogen atmosphere formed by introducing a nitrogen gas into heat insulation container 40 at 100 sccm (Standard Cubic Centimeters per Minute). Further, the pressure in heat insulation container 40 is preferably 50 kPa or smaller, and is more preferably 10 kPa or smaller. For example, the pressure is 100 Pa.

Next, heater 50 heats, by means of first and second heating members 91, 92, single-crystal group 10 and base portion 30 to a temperature at which sublimation/recrystallization reaction takes place. This temperature is normally not less than 1800° C. and not more than 2500° C., for example, is approximately 2000° C. This heating is performed to cause a temperature difference such that the temperature of base portion 30 becomes higher than the temperature of single-crystal group 10. Such a temperature difference can be obtained by providing a temperature gradient in heat insulation container 40. This temperature gradient is preferably not less than 1° C./mm and not more than 200° C./mm, more preferably, not less than 10° C./cm and not more than 50° C./cm.

At the stage of starting the heating, base portion 30 is only placed on each of single-crystal substrates 11 and 12, and is not connected thereto. Thus, as shown in FIG. 7, when viewed microscopically, a space GQ exists between each of the backside surfaces of single-crystal substrates 11 and 12 and main surface P1 of base portion 30. Space GQ has an average height (dimension in the vertical direction in FIG. 7) of several ten μm, for example.

When the above-described temperature gradient causes the temperature of base portion 30 to be higher than that of each of single-crystal substrates 11 and 12, this temperature difference causes mass transfer of silicon carbide, involved in the sublimation and recrystallization. Specifically, sublimation gas of silicon carbide is formed from silicon carbide layer 32 at its portion facing single-crystal substrates 11 and 12, and this gas is recrystallized on single-crystal substrates 11 and 12. Namely, in space GQ, mass transfer takes place from base portion 30 to each of single-crystal substrates 11 and 12 as indicated by arrows Mc in the figure.

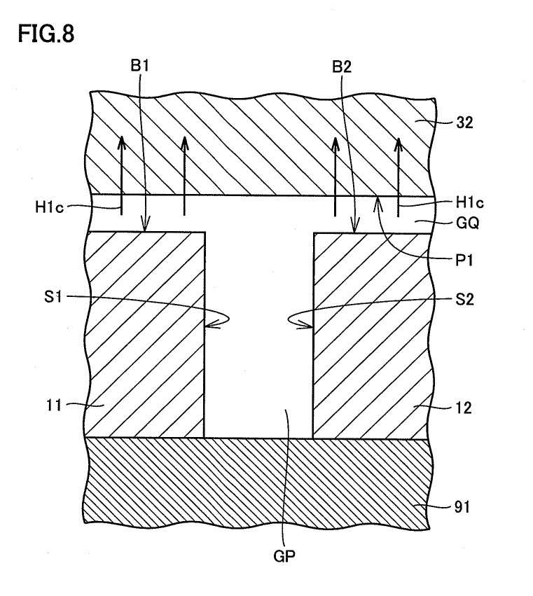

Conversely, referring to FIG. 8, the mass transfer indicated by arrows Mc (FIG. 7) corresponds to transfer of space GQ as indicated by arrows H1c (FIG. 8). Here, there is a large in-plane variation in the height of space GQ (dimension in the vertical direction in the figure), and this variation results in a large in-plane variation in a rate of transfer of space GQ (arrows H1c in the figure).

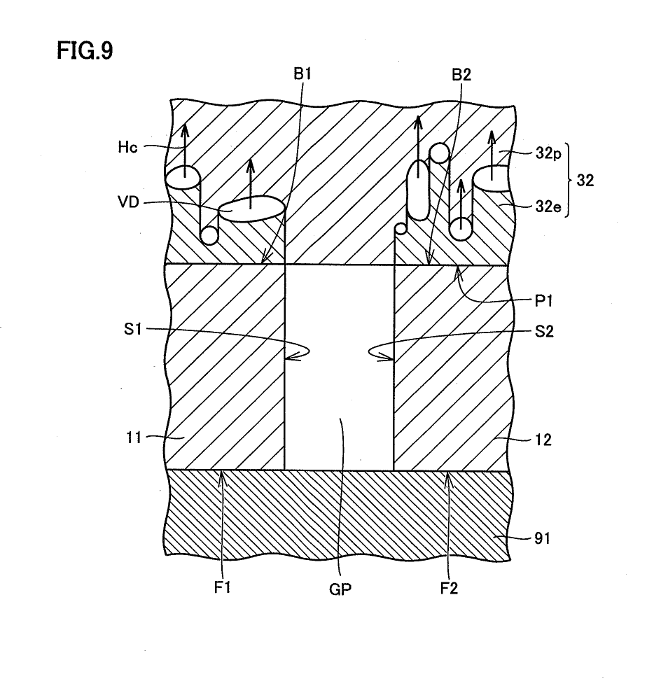

Further, referring to FIG. 9, due to the variation, the vacant space corresponding to space GQ (FIG. 8) cannot keep its shape upon being transferred, resulting in generation of a plurality of voids VD (FIG. 9). Voids VD are transferred as indicated by arrows Hc (FIG. 9), due to the above-described temperature difference. The transfer of the voids corresponds to change of a portion of silicon carbide layer 32 into second region 32e caused by the epitaxial growth on backside surfaces B1 and B2 of single-crystal substrates 11 and 12. Voids VD are located at a boundary between second region 32e and first region 32p, which is a portion not changed into second region 32e in silicon carbide layer 32.

In the manner described above, each of single-crystal substrates 11 and 12 is connected onto silicon carbide layer 32 of base portion 30. Accordingly, combined substrate 81 (FIG. 1-FIG. 3) is obtained.

Next, a method for manufacturing a combined substrate (FIG. 10) of a comparative example will be described. In this comparative example, a base portion 30z and single-crystal substrate 12 are adhered to each other by means of an adhesive agent 29. An interface between adhesive agent 29 and single-crystal substrate 12 and an interface between adhesive agent 29 and base portion 30z are flat, so they are likely to come off at one of the interfaces. Further, the material of single-crystal substrate 12 and the material of adhesive agent 29 are different. Hence, there is a difference in thermal expansion coefficient therebetween, whereby single-crystal substrate 12 and adhesive agent 29 are likely to come off readily. Further, in the case where base portion 30z is formed of silicon carbide, it takes time to fabricate base portion 30z. On the other hand, in the case where base portion 30z is formed of a material other than silicon carbide, adhesive agent 29 adheres single-crystal substrate 12 made of silicon carbide and base portion 30z made of the material other than silicon carbide, i.e., adheres the members made of different types of materials, which is likely to result in insufficient adhesive strength.

In contrast, according to the present embodiment, the connection achieved between each of single-crystal substrates 11-19 and base portion 30 is connection between the members made of silicon carbide. Accordingly, firm connection can be readily achieved as compared with the case of the connection between the members made of the different types of materials as in the above-described comparative example.

Further, silicon carbide layer 32 is supported by supporting layer 31, thereby securing rigidity required for handling of combined substrate 81 even though silicon carbide layer 32 is thin. Thus, no thick silicon carbide layer 32 needs to be formed and base portion 30 can be therefore fabricated for a short time, thereby decreasing manufacturing cost of combined substrate 81.

Further, the interface between single-crystal substrate 11 and second region 32e epitaxially grown thereon, i.e., the interface at which the crystal structures are connected in a substantially continuous manner, corresponds to the connection surface between single-crystal substrate 11 and base portion 30. Accordingly, this connection becomes firm. For the same reason, the connection between each of single-crystal substrates 12-19 and base portion 30 becomes firm.

Preferably, the crystal structures of silicon carbide layer 32 and each one in single-crystal group 10 have the same polytype. This provides a small difference in thermal expansion coefficient therebetween, thereby preventing warpage or crack of combined substrate 81.

Preferably, silicon carbide layer 32 has an impurity concentration higher than that of each in single-crystal substrates 11-19. In other words, the impurity concentration of silicon carbide layer 32 is relatively high and the impurity concentration of each of single-crystal substrates 11-19 is relatively low. Since the impurity concentration of silicon carbide layer 32 of base portion 30 is thus high, an average resistivity of base portion 30 can be small, thereby reducing a resistance for current flowing in combined substrate 81. Meanwhile, since the impurity concentration of each of single-crystal substrates 11-19 is thus low, the crystal defect thereof can be reduced more readily. As the impurity, nitrogen, phosphorus, boron, or aluminum can be used.

Preferably, front-side surface F1 has an off angle of not less than 50° and not more than 65° relative to the (000-1) plane of single-crystal substrate 11. More preferably, the off orientation of front-side surface F1 forms an angle of 5° or smaller with the <1-100> direction of single-crystal substrate 11. More preferably, front-side surface F1 has an off angle of not less than −3° and not more than 5° relative to the (0-33-8) plane in the <1-100> direction of single-crystal substrate 11. More preferably, front-side surface F1 has a plane orientation of (0-33-8) plane. Utilization of such a crystal structure achieves high channel mobility in a semiconductor device that employs single-crystal substrate 11. It should be noted that the “off angle of front-side surface F1 relative to the (0-33-8) plane in the <1-100> direction” refers to an angle formed by an orthogonal projection of a normal line of front-side surface F1 to a projection plane defined by the <1-100> direction and the <0001> direction, and a normal line of the (0-33-8) plane. The sign of positive value corresponds to a case where the orthogonal projection approaches in parallel with the <1-100> direction whereas the sign of negative value corresponds to a case where the orthogonal projection approaches in parallel with the <0001> direction. Further, as a preferable off orientation of front-side surface F1, the following off orientation can be employed apart from those described above: an off orientation forming an angle of 5° or smaller relative to the <11-20> direction of single-crystal substrate 11. In the description above, the preferable examples of the crystal structure of silicon carbide of single-crystal substrate 11 has been illustrated and the same applies to the other single-crystal substrates 12-19.

In the present embodiment, the type of the heating device is of employing a resistive heating method using heater 50 (FIG. 5) but other types may be employed therefor. For example, a high-frequency induction heating method or a lamp annealing method may be employed.

### Second Embodiment

In the present embodiment, the following describes manufacturing of a semiconductor device employing combined substrate 81 (FIG. 1 and FIG. 2). For ease of description, only single-crystal substrate 11 of single-crystal substrates 11-19 may be explained, but each of the other single-crystal substrates 12-19 is handled in substantially the same manner.

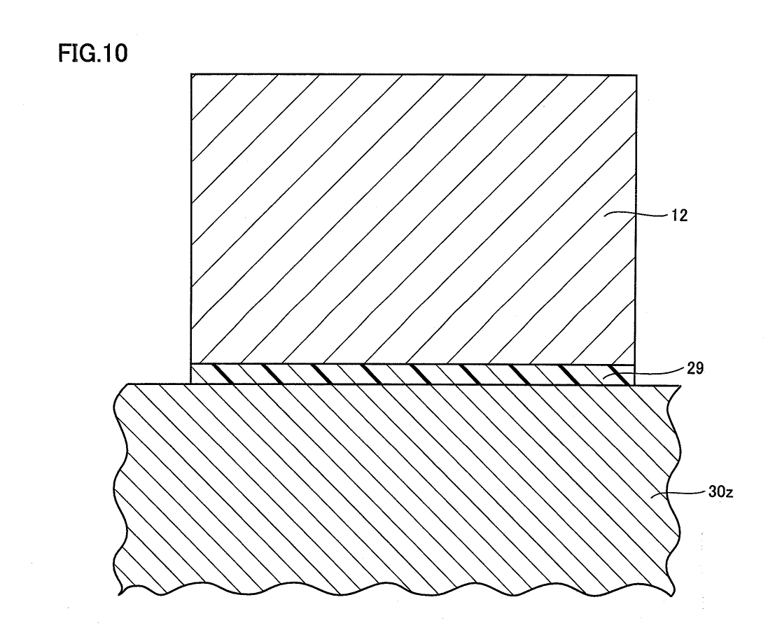

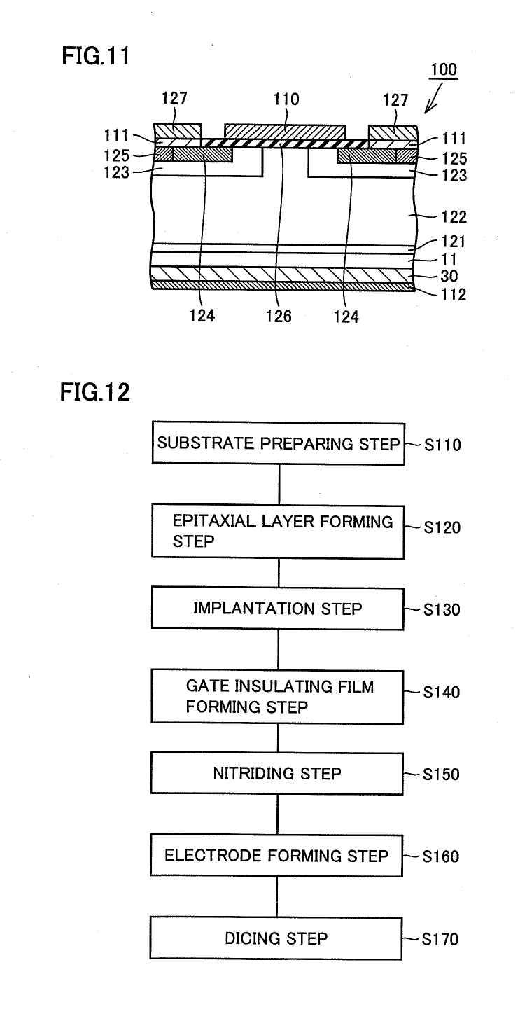

Referring to FIG. 11, a semiconductor device 100 of the present embodiment is a DiMOSFET (Double Implanted Metal Oxide Semiconductor Field Effect Transistor) of vertical type, and has base portion 30, single-crystal substrate 11, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112. Semiconductor device 100 has a planar shape (shape when viewed from upward in FIG. 11) of, for example, a rectangle or a square with sides each having a length of 2 mm or greater.

Drain electrode 112 is provided on base portion 30 and buffer layer 121 is provided on single-crystal substrate 11. With this arrangement, a region in which flow of carriers is controlled by gate electrode 110 is disposed not in base portion 30 but in single-crystal substrate 11.

Each of silicon carbide layer 32 of base portion 30 (FIG. 2), single-crystal substrate 11, and buffer layer 121 has n type conductive type. Impurity with n type conductivity in buffer layer 121 has a concentration of, for example, 5×10¹⁷ cm⁻³. Further, buffer layer 121 has a thickness of, for example, 0.5 μm.

Reverse breakdown voltage holding layer 122 is formed on buffer layer 121, and is made of SiC with n type conductivity. For example, reverse breakdown voltage holding layer 122 has a thickness of 10 μm, and includes a conductive impurity of n type at a concentration of 5×10¹⁵ cm⁻³.

Reverse breakdown voltage holding layer 122 has a surface in which the plurality of p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. Oxide film 126 is formed on reverse breakdown voltage holding layer 122 at its portion exposed between the plurality of p regions 123. Specifically, oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

The maximum value of nitrogen atom concentration is 1×10²¹ cm⁻³ or greater at a region distant away by 10 nm or shorter from an interface between oxide film 126 and each of the semiconductor layers, i.e., n⁺ regions 124, p⁺ regions 125, p regions 123, and reverse breakdown voltage holding layer 122. This achieves improved mobility particularly in a channel region below oxide film 126 (a contact portion of each p region 123 with oxide film 126 between each of n⁺ regions 124 and reverse breakdown voltage holding layer 122).

The following describes a method for manufacturing semiconductor device 100. First, in a substrate preparing step (step S110: FIG. 12), combined substrate 81 (FIG. 1 and FIG. 2) is prepared.

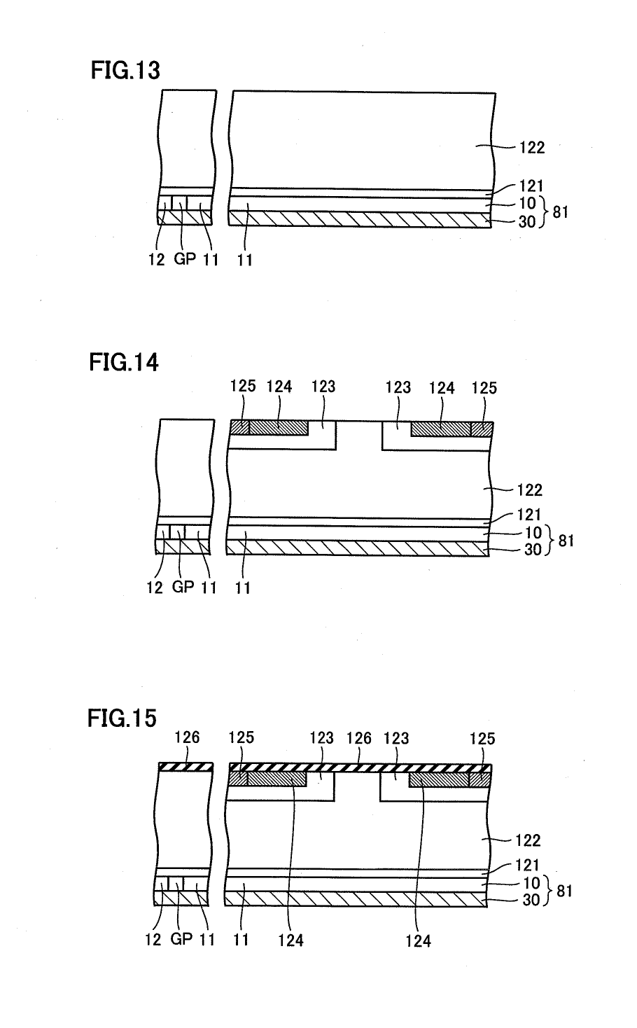

Referring to FIG. 13, in an epitaxial layer forming step (step S120: FIG. 12), buffer layer 121 and reverse breakdown voltage holding layer 122 are formed as follows.

Buffer layer 121 is formed on the front-side surface of single-crystal group 10. Buffer layer 121 is made of SiC of n type conductivity, and is an epitaxial layer having a thickness of 0.5 μm, for example. Buffer layer 121 has a conductive impurity at a concentration of, for example, 5×10¹⁷ cm⁻³.

Next, reverse breakdown voltage holding layer 122 is formed on buffer layer 121. Specifically, a layer made of SiC of n type conductivity is formed using an epitaxial growth method. Reverse breakdown voltage holding layer 122 has a thickness of, for example, 10 μm. Further, reverse breakdown voltage holding layer 122 includes an impurity of n type conductivity at a concentration of for example, 5×10¹⁵ cm⁻³.

Referring to FIG. 14, an implantation step (step S130: FIG. 12) is performed to form p regions 123, n⁺ regions 124, and p⁺ regions 125 as follows.

First, a conductive impurity of p type conductivity is selectively implanted into portions of reverse breakdown voltage holding layer 122, thereby forming p regions 123. Then, a conductive impurity of n type is selectively implanted to predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed. For example, the annealing is performed in argon atmosphere at a heating temperature of 1700° C. for 30 minutes.

Referring to FIG. 15, a gate insulating film forming step (step S140: FIG. 12) is performed. Specifically, oxide film 126 is formed to cover reverse breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitriding step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

Next, an electrode forming step (step S160: FIG. 12) is performed to form source electrodes 111 and drain electrode 112 in the following manner.

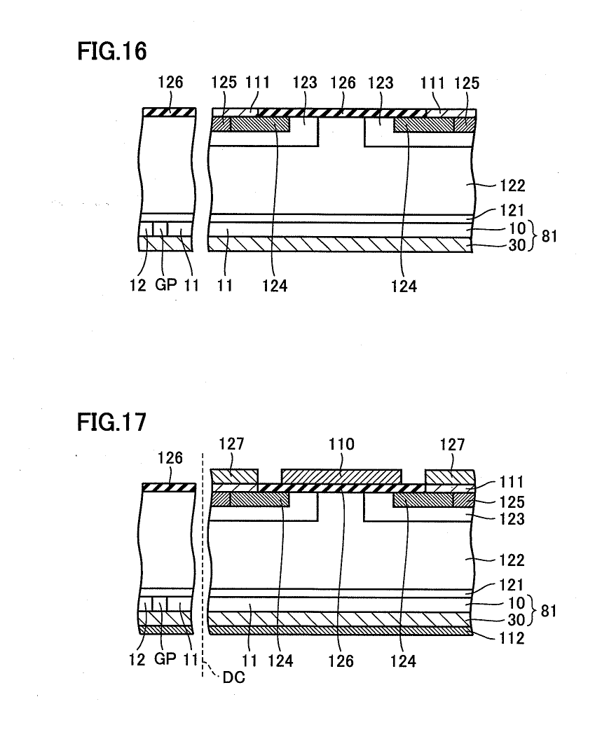

Referring to FIG. 16, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

Referring to FIG. 17 again, upper source electrodes 127 are formed on source electrodes 111. Further, gate electrode 110 is formed on oxide film 126. Further, drain electrode 112 is formed on the backside surface of combined substrate 81.

Next, in a dicing step (step S170: FIG. 12), dicing is performed as indicated by a broken line DC. Accordingly, a plurality of semiconductor devices 100 (FIG. 11) are obtained by the cutting.

According to the method for manufacturing semiconductor device 100 in the present embodiment, combined substrate 81, which is lower in cost than the conventional one, can be used, thereby achieving decreased manufacturing cost of semiconductor device 100.

It should be noted that a configuration may be employed in which conductive types are opposite to those in each of the foregoing embodiments. Namely, a configuration may be employed in which p type and n type are replaced with each other. Further, the DiMOSFET of vertical type has been exemplified, but another semiconductor device may be manufactured using the semiconductor substrate of the present invention. For example, a RESURF-JFET (Reduced Surface Field-Junction Field Effect Transistor) or a Schottky diode may be manufactured.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a combined substrate, comprising the steps of:
preparing a base portion having a supporting layer made of a material different from silicon carbide, and a silicon carbide layer formed on said supporting layer; and
connecting each of first and second silicon carbide single-crystals onto said silicon carbide layer of said base portion.

2. The method for manufacturing the combined substrate according to claim 1, wherein the step of connecting includes:
arranging each of said first and second silicon carbide single-crystals to face said silicon carbide layer; and
connecting said silicon carbide layer to each of said first and second silicon carbide single-crystals by sublimating and recrystallizing, onto said first and second silicon carbide single-crystals, said silicon carbide layer's portions respectively facing said first and second silicon carbide single-crystals.

3. The method for manufacturing the combined substrate according to claim 2, wherein the step of arranging is performed by stacking a single-crystal group and said base portion on each other, said single-crystal group having said first and second silicon carbide single-crystals disposed at different locations when viewed in a planar view.

4. The method for manufacturing the combined substrate according to claim 1, wherein said supporting layer includes a layer made of graphite.

5. The method for manufacturing the combined substrate according to claim 1, wherein said supporting layer includes a layer made of a metal having a melting point higher than a temperature at which silicon carbide is able to sublime.

6. The method for manufacturing the combined substrate according to claim 1, wherein each of said silicon carbide layer, said first silicon carbide single-crystal, and said second silicon carbide single-crystal has a crystal structure of the same polytype.

7. A combined substrate, comprising:
a base portion having a supporting layer made of a material different from silicon carbide, and a silicon carbide layer formed on said supporting layer; and
first and second silicon carbide single-crystals each connected onto said silicon carbide layer of said base portion, said silicon carbide layer having a first region facing said supporting layer, and a second region buried in said first region and epitaxially grown on each of said first and second silicon carbide single-crystals.

8. The combined substrate according to claim 7, wherein said silicon carbide layer has a void between said first and second regions.
